(19) United States
(12) Patent Application Publication
(10) Pub. No.: US 2012/0163097 A1
(43) Pub. Date: Jun. 28, 2012

(54) MEMORY DEVICE, MEMORY CONTROL METHOD, AND PROGRAM

(75) Inventors: Yuya Ishikawa, Tokyo (JP); Shingo Aso, Tokyo (JP)

(73) Assignee: SONY CORPORATION, Tokyo (JP)

(21) Appl. No.: 13/327,242

(22) Filed: Dec. 15, 2011

(30) Foreign Application Priority Data
Dec. 22, 2010 (JP) 2010-286120

(51) Int. Cl. G11C 16/06

(52) U.S. Cl. 365/185.25

(57) ABSTRACT

A memory device includes: a non-volatile memory erasing data in a block unit and writing and reading data to and from a block; and a control unit controlling an access operation to the non-volatile memory, monitoring levels of a data change state of the non-volatile memory, and controlling a refresh operation of the non-volatile memory. The control unit executes the refresh operation in accordance with a comparison result between a plurality of set emergency levels of the refresh operation and the levels of the data change state.

### BACKGROUND

The present disclosure relates to a memory device, a memory control method, and a program having a refresh function of a non-volatile memory.

There is known a memory device including a flash memory, which is a nonvolatile memory, as an external storage device of a personal computer, a digital still camera, a digital video camera, an audio recorder, or the like.

The flash memory executes operations of writing and reading data in a page unit smaller than a block unit at random, and executes an operation of erasing data not at random but in the block unit.

Processes of manufacturing a NAND flash memory, which is a flash memory, have been progressively miniaturized every on year, and thus reliability of data deteriorates. Accordingly, there has been a necessity for a memory controller to include an error correction circuit with higher correction capability.

In the NAND flash memory, the reliability of data has been improved using an error correction code in order to prepare against occurrence of bit change when the written data is read.

However, due to the miniaturization of the processes of manufacturing the NAND flash memory, the bit change of data tends to occur when the written data is repeatedly read or when the written data is left for a long time. Therefore, the bit change tends to occur as the data is not corrected.

In such a condition, there has been suggested a method of setting a situation in which the bit change is scarcely cased so as to not only correct the occurrence of the bit change but also execute a refresh operation during a correction possibility period, as shown in FIG. 1.

In the example of FIG. 1, the refresh operation is executed such that data is read from a block deteriorated in reliability while correcting the data, the read data is corrected using an ECC (Error Correcting Circuit), and the data is written to a block different from the re-read block.

In the suggested refresh method, the refresh operation is executed when the occurrence number of bit changes of the data, the number of times of reading or writing the data, or the like exceeds a given threshold value, that is, when the reliability of data is less than the given threshold value (for example, see Japanese Unexamined Patent Application Publication No. 2009-205578, Japanese Unexamined Patent Application Publication No. 7-220486, and Japanese Unexamined Patent Application Publication No. 8-147988).

### SUMMARY

As described above, according to the suggested refresh method, the refresh operation is executed when the occurrence number of bit changes of the data, the number of times of reading or writing the data, or the like exceeds the given threshold value, that is, when the reliability of data is less than the given threshold value.

FIG. 2 is a schematic diagram of access to a memory device from a host device, a refresh operation, and overhead due to the refresh operation.

For example, a writing or reading command is sent from a host device 1 to a control device 2A of a memory device 2.

The control device 2A executes a writing or reading operation in response to the command to a non-volatile memory 2B. During this period, the non-volatile memory 2B is in a busy state.

The control device 2A executes the refresh operation when the reliability of the data is less than the given threshold value.

However, in the refresh operation, when the reliability of the data is less than the given threshold value, the refresh operation is immediately executed. Therefore, instead of ensuring the reliability of the data, a refresh time corresponds to an overhead time. For this reason, there may be a disadvantage in that the processing speed is lowered.

When the threshold value is increased in order to prevent this problem, the refresh operation is executed in a state where the reliability of the data considerably deteriorates. Therefore, there is a high possibility that data may not be corrected even when the error correction code is used.

On the contrary, when the threshold value is set low, there is a high possibility that the refresh operation has to be executed, thereby easily lowering the processing speed.

It is desirable to provide a memory device, a memory control method, and a program capable of preventing a processing speed from being lowered and realizing an accurate refresh operation depending on the situation.

According to an embodiment of the disclosure, there is provided a memory device including: a non-volatile memory erasing data in a block unit and writing and reading data to and from a block; and a control unit controlling an access operation to the non-volatile memory, monitoring a level of a data change state of the non-volatile memory, and controlling a refresh operation of the non-volatile memory. The control unit executes the refresh operation in accordance with a comparison result between a plurality of set emergency levels of the refresh operation and a level of the data change state.

According to another embodiment of the disclosure, there is provided a memory control method including: accessing a non-volatile memory erasing data in a block unit to write or read data to or from a block; and controlling an access operation to the non-volatile memory, monitoring levels of a data change state of the non-volatile memory, and controlling a refresh operation of the non-volatile memory. In the controlling, the refresh operation is executed in accordance with a comparison result between a plurality of set emergency levels of the refresh operation and the levels of the data change state.

According to still another embodiment of the disclosure, there is provided a program causing a computer to execute a memory control process including: accessing a non-volatile memory erasing data in a block unit to write or read data to or from a block; and controlling an access operation to the non-volatile memory, monitoring levels of a data change state of the non-volatile memory, and controlling a refresh operation of the non-volatile memory. In the controlling, the refresh operation is executed in accordance with a comparison result between a plurality of set emergency levels of the refresh operation and the levels of the data change state.

According to the embodiments of the disclosure, it is possible to prevent a processing speed from being lowered. Accordingly, it is possible to realize an accurate refresh operation in accordance with situations.

### BRIEF DESCRIPTION OF THE DRAWINGS

FIG. 1 is a diagram of a refresh operation during a correction possibility period;

FIG. 2 is a schematic diagram of access to a memory device from a host device, the refresh operation, and overhead of the refresh operation;

FIG. 3 is a diagram of the overall configuration of an information processing system according to an embodiment;

FIG. 4 is a block diagram of an example of a specific configuration of the memory device shown in FIG. 3;

FIG. 5 is a diagram of a reliability of data of a non-volatile memory (flash memory);

FIG. 6 is a diagram of a basic data flow of the refresh operation of the non-volatile memory in the memory device;

FIG. 7 is a flowchart of a basic refresh operation;

FIG. 8 is a diagram of a general refresh operation;

FIG. 9 is a diagram of a refresh method according to the embodiment;

FIGS. 10A to 10C are diagrams of a conversion example of the emergency level in the refresh operation according to the embodiment;

FIG. 11 is a diagram of an example of a refresh list defining the refresh operation in accordance with the emergency level when a threshold value is set using both the occurrence number of bit changes of the data and the number of times the block is accessed;

FIG. 12 is a diagram of a case where values used to determine the reliability are irregular in one block;

FIG. 13 is a flowchart of acquiring a bit error value indicating the reliability in the block;

FIG. 14 is a flowchart of an example of a process executed in accordance with the emergency level by setting the emergency level in accordance with a deterioration (damage) state (data change state) of the data; and

FIGS. 15A and 15B are diagrams of the setting of the threshold value and a grace period up to a correction impossibility state according to the embodiment.

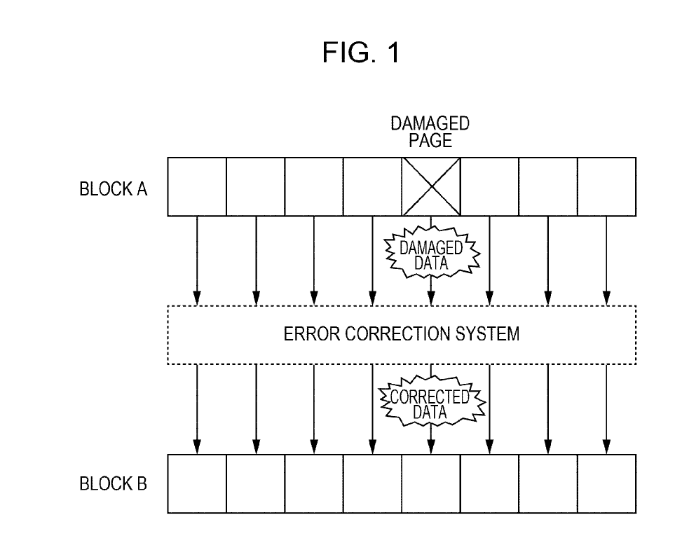

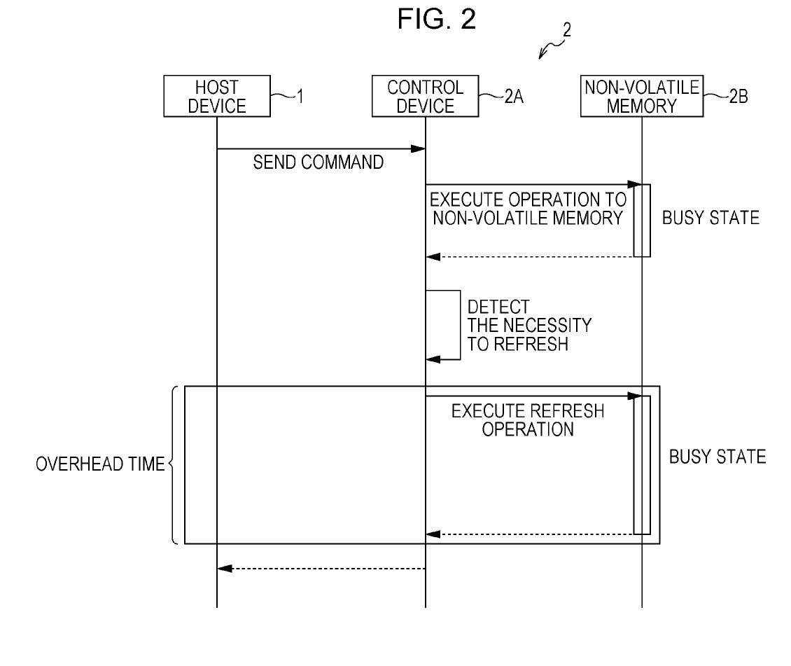

### DETAILED DESCRIPTION OF EMBODIMENTS

Hereinafter, an embodiment of the disclosure will be described with reference to the accompanying drawings.

The description will be made in the following order.
1. Overview of Overall Configuration of Information Processing System
2. Overview of Refresh Operation Control of Memory Device
3. Specific Example of Refresh Operation Control of Memory Device

### 1. Overview of Overall Configuration of Information Processing System

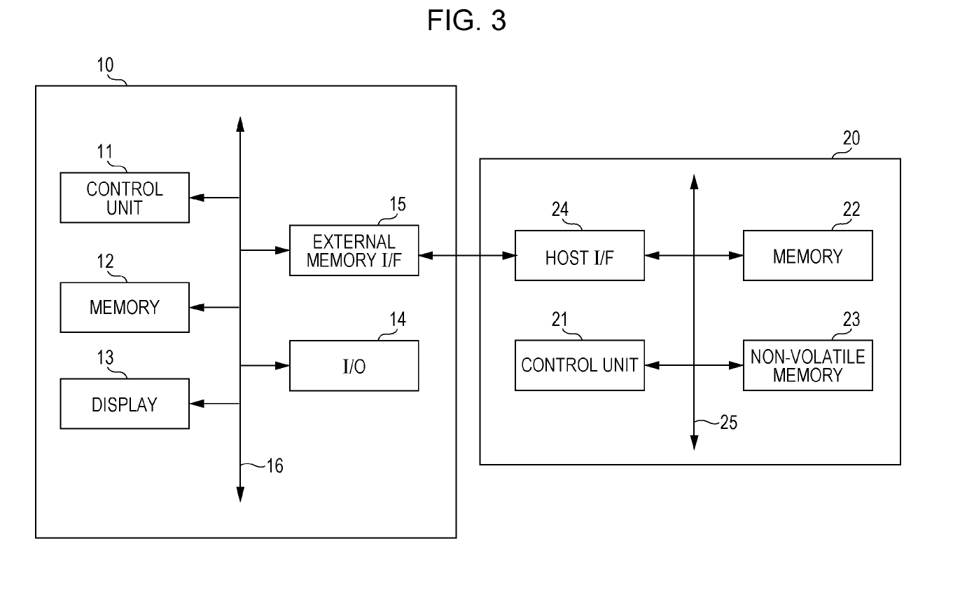

FIG. 3 is a diagram of the general configuration of an information processing system according to an embodiment of the disclosure.

As shown in FIG. 3, the information processing system includes, as main units, a host device 10 and a memory device 20 serving as an information processing device detachably mounted on the host device 10. In this embodiment, the memory device 20 includes a non-volatile memory such as a NAND flash memory.

The host device 10 is configured by a device such as a personal computer (PC), a digital still camera, a digital video camera, or an audio recorder.

The host device 10 includes a control unit 11, a memory 12, a display 13, an input/output (I/O) processing unit 14, and an external memory interface (I/F) 15.

The control unit 11 is connected to the memory 12, the display 13, the I/O unit 14, and the external memory I/F 15 via a bus 16.

The memory 12 includes a ROM for program storage and a RAM as a working memory.

The external memory I/F 15 transmits and receives data to and from the memory device 20 in accordance with a control command of the control unit 11.

The memory device 20 includes a control unit 21, a memory 22, a non-volatile memory 23, and a host I/F 24.

The control unit 21 is connected to the memory 22, the non-volatile memory 23, and the host I/F 24 via a bus 25.

The memory 22 includes a ROM for program storage and a RAM as a working memory. For example, the memory 22 includes an internal RAM and a buffer RAM.

The non-volatile memory 23 is configured by, for example, a NAND or NOR-type flash memory. In this embodiment, the NAND flash memory will be exemplified as the non-volatile memory.

The host I/F 24 transmits and receives data to and from the host device 10 in accordance with a control command of the control unit 21.

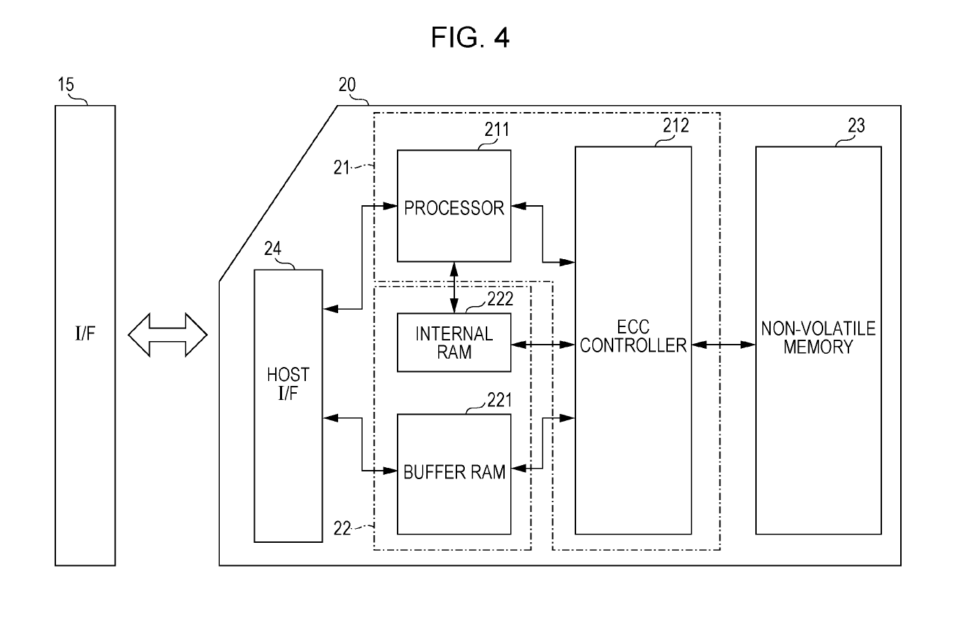

FIG. 4 is a block diagram of a more specific example of the configuration of the memory device 20 shown in FIG. 3.

When the memory device 20 is mounted on the host device 10, data supplied from the host device 10 is written and stored data is read.

The memory device 20 includes a processor 211 serving as the control unit 21 and an ECC controller 212 having a function of an error correction unit.

The memory 22 includes a buffer RAM 221 and an internal RAM 222.

The processor 211 executes the entire control of the memory device 20. For example, the processor 211 controls transmission of a command or data to the host device 10 through the host I/F 24 and controls writing or reading to or from the non-volatile memory 23 through the ECC controller 212.

The ECC controller 212 has a function of improving reliability of data by adding an error correction code to the data to be written, if necessary, and writing the data to the non-volatile memory 23 under the control of the processor 211 and by detecting and correcting an error when reading the data.

The ECC controller 212 executes a refresh operation in order to improve the reliability of the data depending on the state of the non-volatile memory 23 under the control of the processor 211. The ECC controller 212 has a function of determining a threshold value, which is used to determine whether to execute the refresh operation, into a plurality of steps, as described in detail below.

In the refresh operation, the ECC controller 212 saves data read from one block of the non-volatile memory 23 temporarily to the internal RAM 222 and writes back the saved data to another block.

In a non-refresh operation which is not the refresh operation, the ECC controller 212 executes processing on data temporarily retained in the buffer RAM 221.

For example, the non-volatile memory 23 configured by the NAND flash memory erases data in a block unit and writes or reads data to or from the blocks in, for example, a page unit which is smaller than the block unit.

### 2. Overview of Refresh Operation Control of Memory Device

Hereinafter, the overview of the refresh operation of the memory device 20 according to the embodiment will be described.

In this embodiment, the ECC controller 212 of the control unit 21 monitors the level of a data change state of the non-volatile memory 23 under the control of the processor 211 and controls the refresh operation of the non-volatile memory 23.

The ECC controller 212 executes the refresh operation in accordance with the comparison result which is the level of a data change state got by monitoring the plurality of set emergency levels of execution of the refresh operations.

The level of the data change state is information used to determine the reliability of data.

A value necessary to set the emergency level and used to determine the reliability of data may be any value as a condition, such as the occurrence number of bit changes of the data, the number of times of writing the data, the number of times of reading the data, or an elapsed time after the writing.

In this embodiment, for example, at least a first threshold value TH1 corresponding to a high emergency level and a second threshold value TH2 corresponding to a low emergency level are set as a plurality of degrees of urgency.

When the level of the data change state is equal to or greater than the second threshold value TH2 and is less than the first threshold value TH1, the ECC controller 212 of the control unit 21 determines that the emergency level is low, and thus does not execute the refresh operation immediately and executes the refresh operation at a timing at which there is no influence on the performance of the system.

Here, the timing at which there is no influence on the performance of the system refers to a period, such as an idle period, in which there is no load of the processor 211 or the ECC controller 212 or the load is small.

When the level of the data change state reaches the first threshold value TH1, the ECC controller 212 determines that the emergency level is high, and thus executes the refresh operation immediately.

In this embodiment, as exemplified later, a third threshold value TH3 corresponding to the emergency level less than the emergency level corresponding to the second threshold value TH2 is set as one of the plurality of degrees of urgency.

Further, a fourth threshold value TH4 regarding the number of times the non-volatile memory 23 is accessed or an elapsed time (left time) from the writing of data to the non-volatile memory 23 is set as one of the plurality of degrees of urgency.

When the level of the data change state is equal to or greater than the third threshold value TH3 and is equal to or less than the second threshold value TH2, the ECC controller 212 executes control so as not to execute the refresh operation.

When the number of times the non-volatile memory 23 is accessed or a left time which the non-volatile memory 23 is to be left reaches the fourth threshold value TH4, the ECC controller 212 executes the following control.

In this case, even when the level of the data change state is equal to or greater than the third threshold value TH3 and is equal to or less than the second threshold value TH2, the ECC controller 212 executes control so as to execute the refresh operation.

When the level of the data change state is irregular, in one block of the non-volatile memory 23, the ECC controller 212 applies the level corresponding to the highest emergency level and executes comparison with the plurality of set emergency levels of the refresh operations.

The ECC controller 212 reads the data from the non-volatile memory 23, sets the emergency level in accordance with the change state of the read data, and executes the refresh operation in accordance with the set emergency level.

In this case, when the set emergency level is lower than a preset level, the ECC controller 212 does not execute the refresh operation immediately but executes control so as to execute the refresh operation at the timing at which there is no influence on the performance of the system.

When the set emergency level reaches the preset level, the ECC controller 212 executes control so as to perform the refresh operation immediately.

3. Specific Example of Refresh Operation Control of Memory Device

Next, a specific control example of the refresh operation in the memory device 20 according to the embodiment will be described with reference to the drawings.

Hereinafter, the characteristics of the flash memory and the reason for executing the refresh operation according to the embodiment will be described although the above description may be repeated.

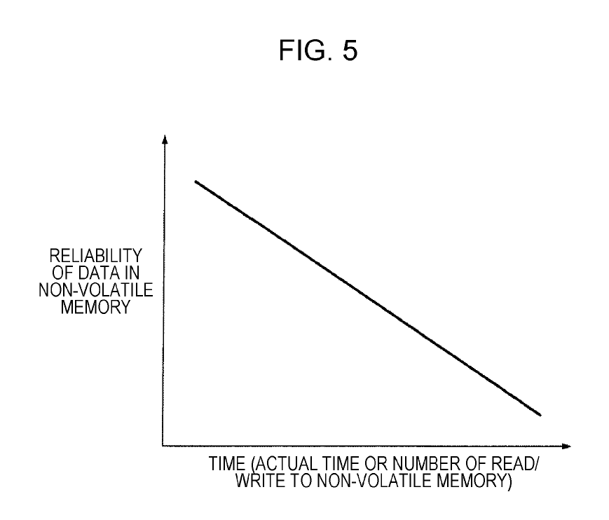

FIG. 5 is a diagram of the reliability of the data of the non-volatile memory (flash memory). In FIG. 5, the horizontal axis represents an actual time of reading or writing the data from or to the non-volatile memory and the vertical axis represents a relative value of the reliability of degree in the non-volatile memory.

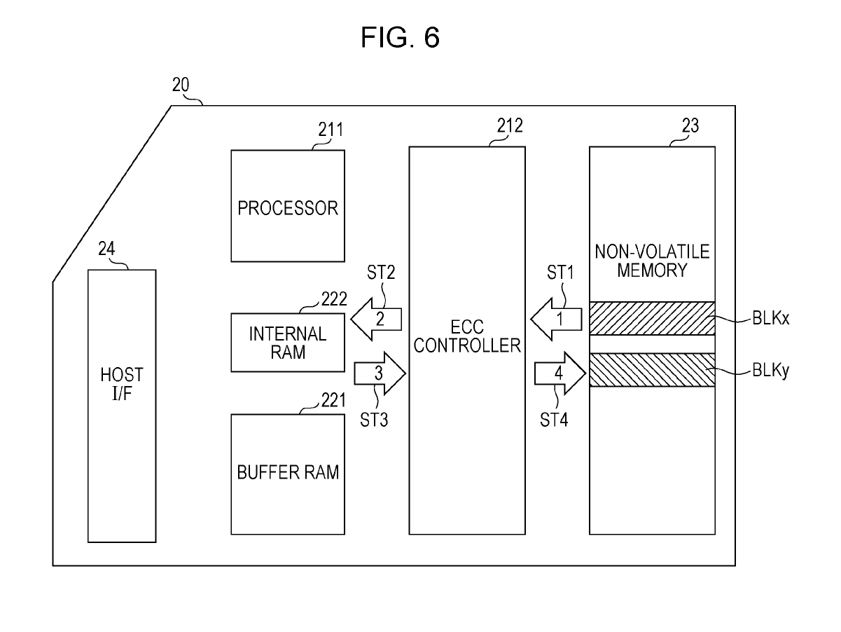

FIG. 6 is a diagram of a basic data flow of the refresh operation of the non-volatile memory in the memory device.

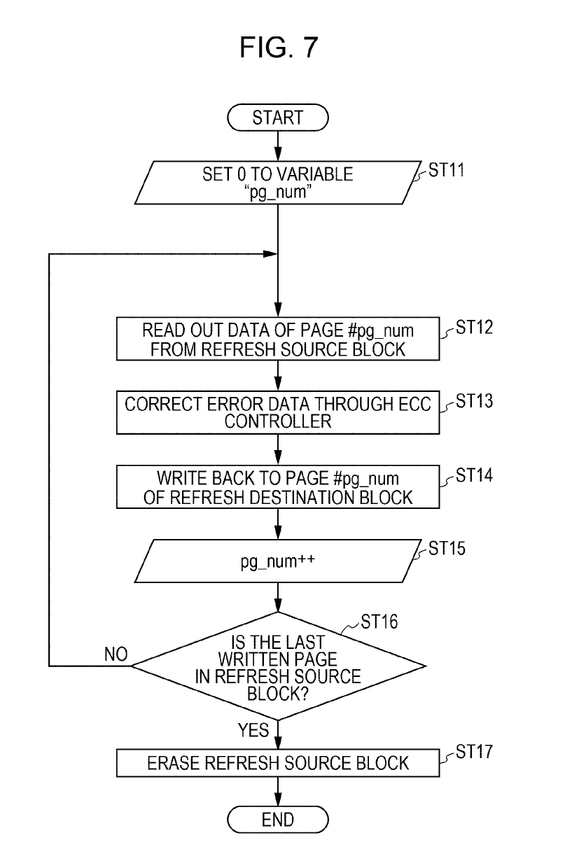

FIG. 7 is a flowchart of a basic refresh operation.

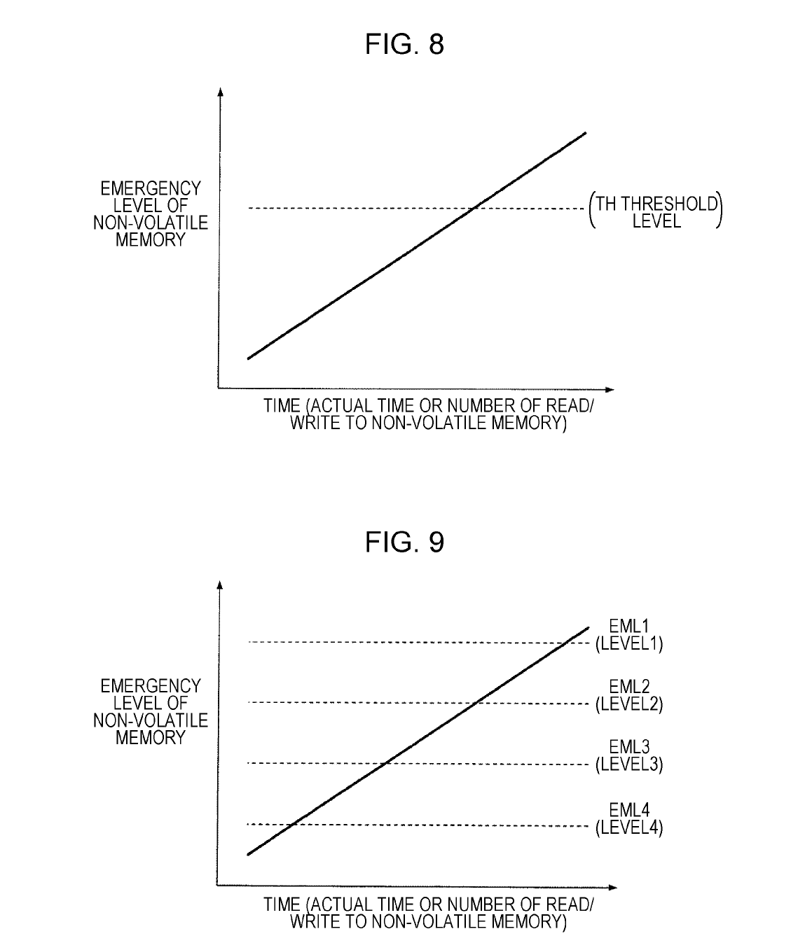

FIG. 8 is a diagram of a general refresh method.

FIG. 9 is a diagram of a refresh method according to this embodiment.

In FIGS. 8 and 9, the horizontal axis represents an actual time of reading or writing the data from or to the non-volatile memory and the vertical axis a relative value of the emergency level of the execution of the refresh operation of the non-volatile memory.

The memory device 20 according to the embodiment uses a semiconductor non-volatile memory as a main storage medium, as shown in FIG. 4.

As shown in FIG. 5, the non-volatile memory 23 configured by the flash memory has a characteristic in which the reliability of the data deteriorates when the actual time is elapsed or the reading or writing operation is repeatedly executed.

In the information processing system, a refresh method is used as a method of preventing the reliability of the data from deteriorating.

In the refresh operation, as shown in FIG. 6, the ECC controller 212 reads data from the non-volatile memory 23 (ST1 and ST2) while correcting the data from a block BLKx deteriorated in reliability, and then corrects the read data using the ECC or the like. Then, the ECC controller 212 executes the refresh operation of writing the corrected data to a block BLKy different from the block of the non-volatile memory 23 from which the data is read again (ST3 and ST4).

As a specific process, a process shown in FIG. 7 is executed.

First, a variable pg is set to 0 (ST11) and data of a predetermined page number is read from a refresh source block (ST12).

Then, the correction of the data is executed through the ECC controller 212 (ST13) and the data is written back to a predetermined page number of a refresh destination block different from that of the reading (ST14).

The variable pg is increased (ST15), and then the process is repeated from step ST12 up to the last page to which the refresh source block is written (ST16).

When the process of writing back the data up to the last page, the refresh source block is erased (ST17).

At a timing of the refresh operation, generally, when the value indicating the reliability is less than the given threshold value TH, as shown in FIG. 8, the method of refreshing the data on the non-volatile memory is used.

In this embodiment, a value indicating one kind of reliability or values indicating a plurality of kinds of reliabilities are used. As shown in FIG. 9, two or more emergency levels, that is, a plurality of emergency levels EML1 to EML4 is provided, a plurality of reliabilities, that is, a plurality of emergency levels is converted, and the refresh operation is executed in accordance with the emergency levels.

As described above, the values necessary to set the emergency levels and used to determine the reliabilities may be any values as a condition, such as the occurrence number of bit changes of the data, the number of times of writing the data, the number of times of reading the data, or an elapsed time after the writing.

When the emergency levels are set (converted), the emergency levels may be set based on a value used to determine a single reliability or may be set a plurality of values.

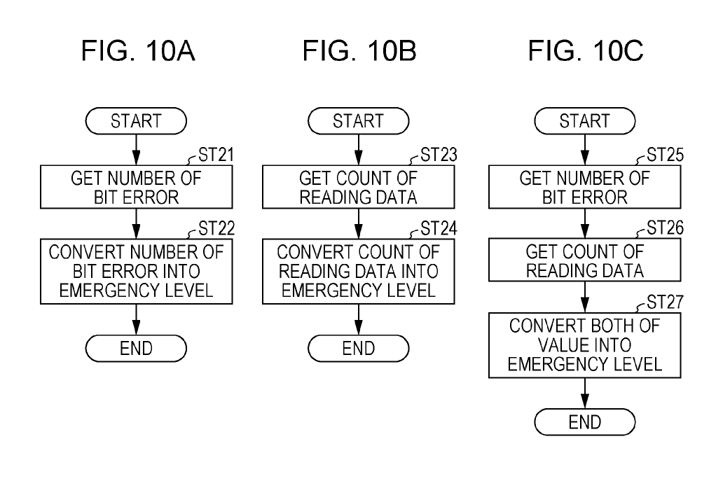

FIGS. 10A to 10C are diagrams of a conversion example of the refresh operation according to this embodiment.

In an example of FIG. 10A, the number of bit errors is acquired (ST21), and then the number of bit errors is converted into the emergency level (ST22).

In an example of FIG. 10B, the count value of the read data is acquired (ST23), and then the count value of the read data is converted into the emergency level (ST24).

In an example of FIG. 10C, the number of error bits is acquired (ST25), the count value of the read data is acquired (ST26), and then both the number of bit errors and the count value of the read data are converted into the emergency level (ST27).

A more specific example will be described.

For example, when the occurrence number of bit changes of the data is used, the threshold values of a plurality of steps are set as follows.

In this example, a 1-bit error is allocated as the third threshold value TH3.

The number of bit errors (which is a value defined by a manufacturer of the non-volatile memory) occurring in the reading or writing operation is allocated as the second threshold value TH2.

The maximum number of bit errors which can be corrected by the ECC controller 212 is allocated as the first threshold value TH1.

For example, the third threshold value TH3 is set to monitor whether an error occurs.

In the second threshold value TH2, the number of bit errors occurring irrespective of the deterioration in the reliability of the non-volatile memory is set.

In the first threshold value TH1, a limit point ensuring the validity of the data immediately before correction impossibility is set.

With such a configuration, the ECC controller 212 does not execute the refresh operation when the threshold value is equal to or greater than the third threshold value TH3 and is equal to or less than the second threshold value TH2.

When the threshold value exceeds the second threshold value TH2, the ECC controller 212 executes the refresh operation at a timing at which there is no influence on the performance of the system.

When the threshold value is the third threshold value TH3, the ECC controller 212 can execute a process in accordance with the emergency degree, for example, can execute the refresh operation immediately.

The threshold value can be set also using the number of times the block is accessed as well as the occurrence number of bit changes of the data.

In this case, the fourth threshold value TH4 corresponding to the number of times the block is accessed is set as well as the first threshold value TH1, the second threshold value TH2, and the third threshold value TH3.

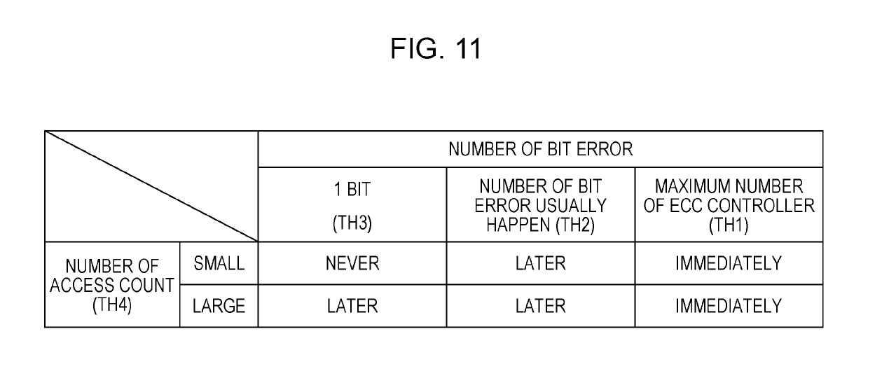

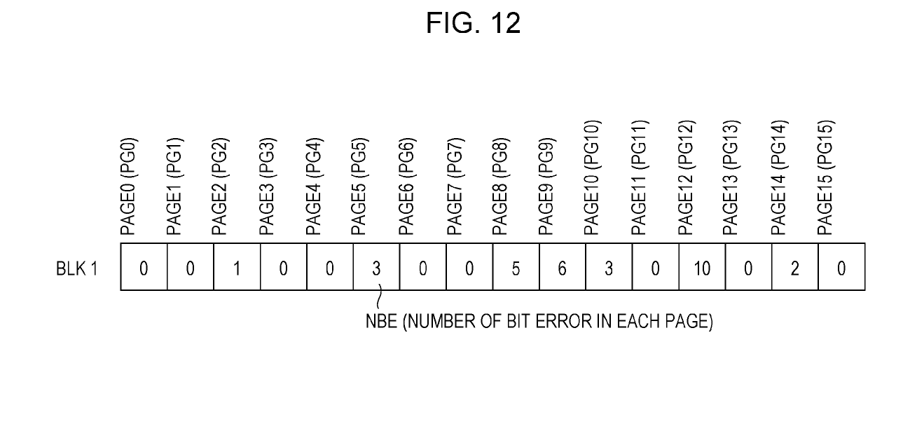

FIG. 11 is a diagram of an example of a refresh list which defines the refresh operation in accordance with the emergency level when the threshold values are set using both the occurrence number of bit changes of the data and the number of times the block is accessed according to this embodiment.

In FIG. 11, a case indicating “later” is a case where the refresh operation is executed at the timing at which there is no performance of the system.

A case indicating “immediately” is a case where the refresh operation is executed immediately (instantly).

A case indicating “never” is a case where the refresh operation is not executed.

A case indicating “small” is a case where the number of times the non-volatile memory 23 is accessed is less than the fourth threshold value TH4 or equal to or less than the fourth threshold value TH4.

A case indicating “large” is a case where the number of times of the non-volatile memory 23 is accessed is equal to or greater than the fourth threshold value TH4 or is greater than the fourth threshold value TH4.

In the example, when the number of times the non-volatile memory 23 is accessed is less than the fourth threshold value TH4 or is equal to or less than the fourth threshold value TH4, a process is executed as follows.

The ECC controller 212 does not execute the refresh operation, when the threshold value is equal to or greater than the third threshold value TH3 and is equal to or less than the second threshold value TH2.

When the threshold value exceeds the second threshold value TH2, the ECC controller 212 executes the refresh operation at the timing at which there is no influence on the performance of the system.

When the threshold value is the third threshold value TH3, the ECC controller 212 executes the refresh operation immediately.

When the number of times the non-volatile memory 23 is accessed is equal to or greater than the fourth threshold value TH4 or is greater than the fourth threshold value TH4, a process is executed as follows in consideration of deterioration over time.

When the threshold value is equal to or greater than the third threshold value TH3 and is equal to or less than the second threshold value TH2, the ECC controller 212 executes the refresh operation at the timing at which there is no influence on the performance of the system.

When the threshold value exceeds the second threshold value TH2, the ECC controller 212 executes the refresh operation at the timing at which there is no influence on the performance of the system.

When the threshold value is the third threshold value TH3, the ECC controller 212 executes the refresh operation immediately.

FIG. 12 is a diagram of a case where values used to determine the reliability are irregular in one block.

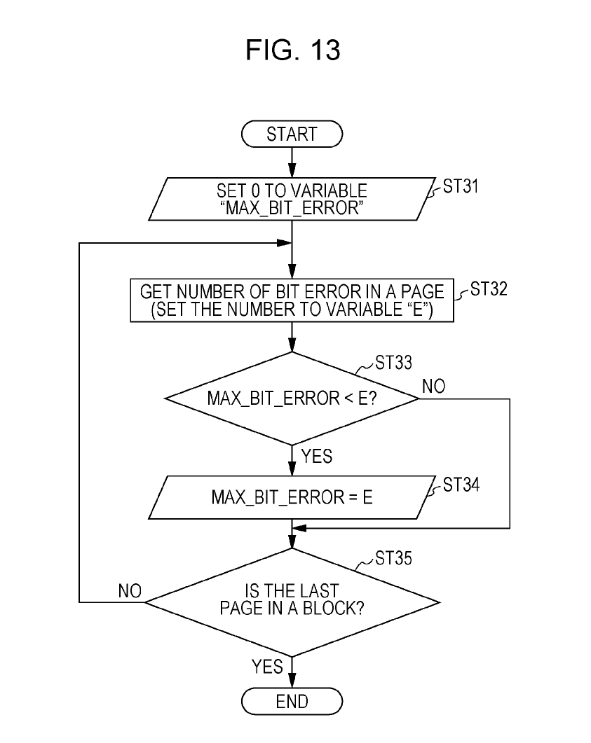

FIG. 13 is a flowchart of acquiring a bit error value indicating the reliability in a block.

In an example of FIG. 12, there are sixteen pages PG0 to PG15 in one block BLK1.

The numerals given to the respective pages PG0 to PG15 indicate the number of bit errors NBE of each page.

In the example of FIG. 12, the number of bit errors NBE of page PG0 is “0”, the number of bit errors NBE of page PG1 is “0”, the number of bit errors NBE of page PG2 is “1”, and the number of bit errors NBE of page PG3 is “0.”

The number of bit errors NBE of page PG4 is “0”, the number of bit errors NBE of page PG5 is “3”, the number of bit errors NBE of page PG6 is “0”, and the number of bit errors NBE of page PG7 is “0.”

The number of bit errors NBE of page PG8 is “5”, the number of bit errors NBE of page PG9 is “6”, the number of bit errors NBE of page PG10 is “3”, and the number of bit errors NBE of page PG11 is “0.”

The number of bit errors NBE of page PG12 is “10”, the number of bit errors NBE of page PG13 is “0”, the number of bit errors NBE of page PG14 is “2”, and the number of bit errors NBE of page PG15 is “0.”

Thus, when the values used to determine the reliability are irregular in one block BLK1, here, the numbers of bit errors NBE are irregular, the emergency level is set based on the low reliability among the values.

Here, the emergency level is set based on the number of bit errors NBE “10” of page PG12.

A process shown in FIG. 13 is executed as a specific process.

First, a variable MAX_BIT_ERROR is set to 0 (ST31), the number of bit errors in a page is acquired. At this time, the variable is set to E (ST32).

When the variable MAX_BIT_ERROR is less than the set value E (ST33), a relation of MAX_BIT_ERROR=E is set (ST34) and the process is repeated up to the last page from step ST32 (ST35).

In the refresh operation executed in accordance with the emergency level, even when the refresh operation is executed immediately at the expense of the performance or even when the refresh operation is executed at the timing at which there is no influence on the performance, the refresh operation may not be executed in a case where the emergency level is low.

A list (refresh list) for retaining information regarding a region where the refresh operation is not executed immediately may be stored temporarily on a volatile memory in the system or may be stored on the non-volatile memory 23.

In this embodiment, after the data is read from the non-volatile memory, the emergency level may be set in accordance with the deterioration (damage) state (data change state) of the read data and the process may be executed in accordance with the emergency level.

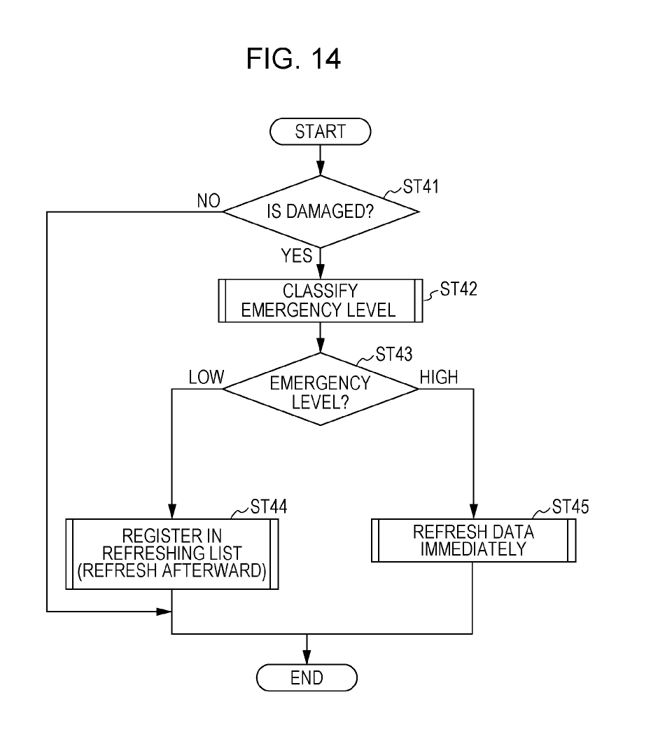

FIG. 14 is a flowchart of an example of a process executed in accordance with the emergency level by setting the emergency level in accordance with a deterioration (damage) state (data change state) of the data.

After the data is read from the non-volatile memory 23, which is a non-volatile memory, the deterioration (damage) state (data change state) of the read data is determined (ST41).

When the data deteriorates, the emergency level is classified in accordance with the degree of deterioration (ST42).

When the classified (set) emergency level is lower than the preset level (ST43), the refresh operation is not executed immediately and is executed at the timing at which there is no influence on the performance on the system (ST44).

When the classified (set) emergency level reaches the preset level (ST43), the refresh operation is executed immediately in that the emergency level is high (ST45).

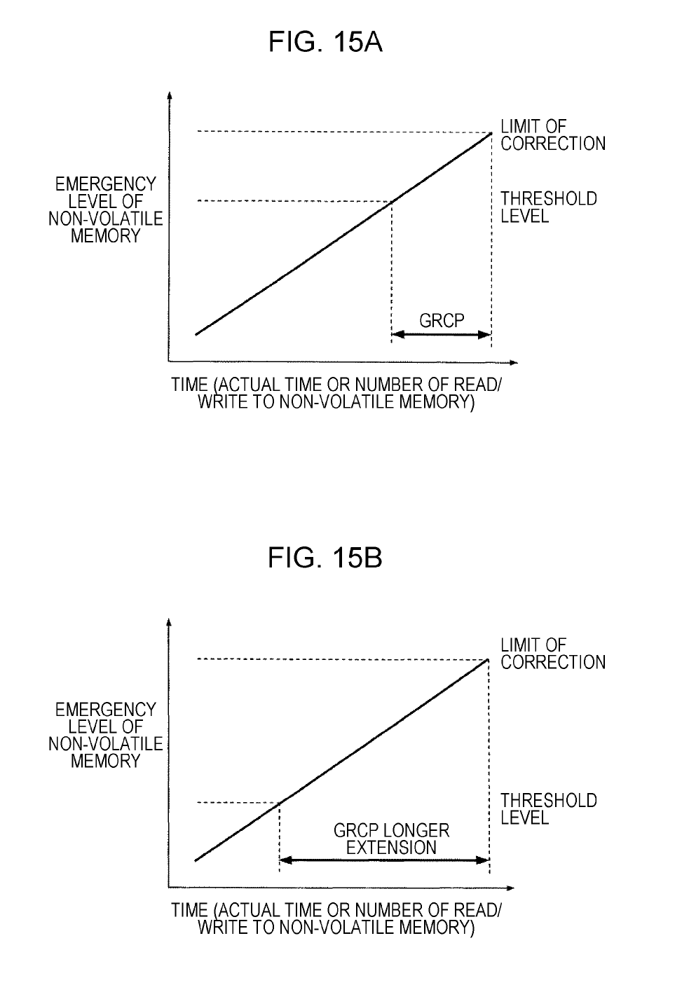

FIGS. 15A and 15B are diagrams of the setting of the threshold value and a grace period up to a correction impossibility state according to the embodiment.

In this embodiment, when the threshold value exceeds a low threshold value at which the reliability of the data starts to deteriorate, the processing speed is prevented from being lowered by setting the data to be refreshed and sequentially executing the refresh operation at an idle time at which the processing speed of the system is not lowered.

Even when there is an interval in which the deterioration in the reliability is detected and then the refresh operation may not be executed by lowering the threshold value, the refresh operation can be executed in a correctable state by the use of the error correction code due to the fact that there is a grace period GRCP shown in FIGS. 15A and 15B.

As described above, the following advantages can be got according to this embodiment.

In the method according to the related art, when the occurrence number of bit changes of the data, the number of times of reading or writing the data, or the like exceeds the threshold value, the refresh operation has to be executed immediately, thereby lowering the processing speed. When the threshold value is increased in order to prevent the processing speed from being lowered, the refresh operation is executed in a case where the reliability of the data considerably deteriorates. Therefore, there is a high possibility that the data may not be corrected even when the error correction code is already used. On the contrary, when the threshold value is set to be low, there is a high possibility that the refresh operation has to be executed, thereby easily causing the deterioration in the processing speed.

In this embodiment, when the occurrence number of bit changes of the data, the number of times of reading or writing the data, or the like exceeds the low threshold value at which the reliability of the data starts to deteriorate, the processing speed is prevented from being lowered by setting the data to be refreshed and sequentially executing the refresh operation at an idle time at which the processing speed of the system is not lowered.

Even when there is an interval in which the deterioration in the reliability is detected and then the refresh operation may not be executed by lowering the threshold value, the refresh operation can be executed in a correctable state by the use of the error correction code.

Further, there is provided a high threshold value at which the reliability considerably deteriorates. The refresh operation can be executed on the data exceeding this threshold value at the expense of the processing speed.

Thus, when the working rate of the system is not considerably high, the refresh operation can be executed early. Therefore, the reliability of the data can be further improved.

Embodiments of the disclosure are not limited to the above-described embodiment, but may be modified appropriately without departing from the gist of the disclosure.

The method described in detail above can be formed by a program in accordance with the above-described order and the program may be executed by a computer including a CPU.

The program may be stored in a recording medium such as a semiconductor memory, a magnetic disk, an optical disc, or a floppy disk (registered trademark). The program may be executed through access by a computer in which the recording medium is set.

The present disclosure contains subject matter related to that disclosed in Japanese Priority Patent Application JP 2010-286120 filed in the Japan Patent Office on Dec. 22, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A memory device comprising:
a non-volatile memory erasing data in a block unit and writing and reading data to and from a block; and
a control unit controlling an access operation to the non-volatile memory, monitoring levels of a data change state of the non-volatile memory, and controlling a refresh operation of the non-volatile memory,
wherein the control unit executes the refresh operation in accordance with a comparison result between a plurality of set emergency levels of the refresh operation and the levels of the data change state.

2. The memory device according to claim 1,
wherein a first threshold value corresponding to a high emergency level and a second threshold value corresponding to a low emergency level are at least set as the plurality of emergency levels, and
wherein the control unit does not execute the refresh operation immediately and executes the reference operation at a timing at which there is no influence on performance of a system, when the level of the data change state is equal to or greater than the second threshold value and is less than the first threshold value, whereas the control unit executes the refresh operation immediately when the level of the data change state reaches the first threshold value.

3. The memory device according to claim 2,
wherein a third threshold value corresponding to an emergency level lower than the emergency level corresponding to the second threshold value is set as one of the plurality of emergency levels, and
wherein the control unit does not execute the refresh operation, when the level of the data change state is equal to or greater than the third threshold value and is equal to or less than the second threshold value.

4. The memory device according to claim 3,
wherein a fourth threshold value regarding the number of times the non-volatile memory is accessed or a time which the non-volatile memory is to be left is set as one of the plurality of emergency levels, and
wherein the control unit executes the refresh operation in spite of the fact that the level of the data change state is equal to or greater than the third threshold value and is equal to or less than the second threshold value, when the number of times the non-volatile memory is accessed or the time which the non-volatile memory is to be left reaches the fourth threshold value.

5. The memory device according to claim 1, wherein the control unit applies a level corresponding to the highest emergency level and executes a process of comparing the level corresponding to the highest emergency level to the plurality of set emergency levels of the refresh operation, when the levels of the data change state are irregular in one block.

6. The memory device according to claim 1, wherein the control unit reads the data from the non-volatile memory, sets the emergency level in accordance with a change state of the read data, and then executes the refresh operation in accordance with the set emergency level.

7. The memory device according to claim 6, wherein the control unit does not execute the refresh operation immediately and executes the refresh operation at a timing at which there is no influence on performance of a system, when the set emergency level is less than the preset level, whereas the control unit executes the refresh operation immediately when the set emergency level reaches the preset level.

8. The memory device according to a claim 1, wherein the control unit includes
an error correction unit writing the data to the non-volatile memory by adding an error correction code to the data to be written, if necessary, and executes error detection and correction at a reading time.

9. A memory control method comprising:
accessing a non-volatile memory erasing data in a block unit to write or read data to or from a block; and
controlling an access operation to the non-volatile memory, monitoring levels of a data change state of the non-volatile memory, and controlling a refresh operation of the non-volatile memory,
wherein in the controlling, the refresh operation is executed in accordance with a comparison result between a plurality of set emergency levels of the refresh operation and the levels of the data change state.

10. The memory control method according to claim 9,
wherein a first threshold value corresponding to a high emergency level and a second threshold value corresponding to a low emergency level are at least set as the plurality of emergency levels, and
wherein in the controlling, the refresh operation is not executed immediately and the reference operation is executed at a timing at which there is no influence on performance of a system, when the level of the data change state is equal to or greater than the second threshold value and is less than the first threshold value, whereas the refresh operation is executed immediately when the level of the data change state reaches the first threshold value.

11. The memory control method according to claim 10,
wherein a third threshold value corresponding to an emergency level lower than the emergency level corresponding to the second threshold value is set as one of the plurality of emergency levels, and
wherein in the controlling, the refresh operation is not executed, when the level of the data change state is equal to or greater than the third threshold value and is equal to or less than the second threshold value.

12. The memory control method according to claim 11,
wherein a fourth threshold value regarding the number of times the non-volatile memory is accessed or a time which the non-volatile memory is to be left is set as one of the plurality of emergency levels, and
wherein in the controlling, the refresh operation is executed in spite of the fact that the level of the data change state is equal to or greater than the third threshold value and is equal to or less than the second threshold value, when the number of times the non-volatile memory is accessed or the time which the non-volatile memory is to be left reaches the fourth threshold value.

13. The memory control method according to claim 9, wherein in the controlling, a level corresponding to the highest emergency level is applied and a process of comparing the level corresponding to the highest emergency level to the plurality of set emergency levels of the refresh operation is executed, when the levels of the data change state are irregular in one block.

14. The memory control method according to claim 9, wherein in the controlling, the data is read from the non-volatile memory, the emergency level is set in accordance with a change state of the read data, and then the refresh operation is executed in accordance with the set emergency level.

15. The memory control method according to claim 14, wherein in the controlling, the refresh operation is not executed immediately and the refresh operation is executed at a timing at which there is no influence on performance of a system, when the set emergency level is less than the preset level, whereas the refresh operation is executed immediately when the set emergency level reaches the preset level.

16. The memory control method according to claim 9, wherein in the controlling, the data is written to the non-volatile memory by adding an error correction code to the data to be written, if necessary, and error detection and correction are executed at a reading time.

17. A program causing a computer to execute a memory control process including:
accessing a non-volatile memory erasing data in a block unit to write or read data to or from a block; and
controlling an access operation to the non-volatile memory, monitoring levels of a data change state of the non-volatile memory, and controlling a refresh operation of the non-volatile memory,
wherein in the controlling, the refresh operation is executed in accordance with a comparison result between a plurality of set emergency levels of the refresh operation and the levels of the data change state.
